(19) United States
(12) Patent Application Publication
(10) Pub. No.: US 2023/0187426 A1
(43) Pub. Date: Jun. 15, 2023

(54) INTEGRATED CIRCUIT LAYOUT AND INTEGRATED CIRCUIT LAYOUT METHOD FOR FILTER

(71) Applicant: REALTEK SEMICONDUCTOR CORP., HSINCHU (TW)

(72) Inventors: CHIA-WEI YU, HSINCHU (TW); YUNG-TAI CHEN, HSINCHU (TW); CHAO-YANG CHEN, HSINCHU (TW); SHENG-YANG HO, HSINCHU (TW)

(21) Appl. No.: 18/075,502

(22) Filed: Dec. 6, 2022

(30) Foreign Application Priority Data
Dec. 14, 2021 (TW) 110146660

(51) Int. Cl. H01L 25/16; H01L 23/528; H01L 23/532; H01L 29/78

(52) U.S. Cl. CPC H01L 25/162; H01L 28/40; H01L 23/528; H01L 23/53209; H01L 28/20; H01L 29/785

(57) ABSTRACT

An integrated circuit layout and an integrated circuit layout method for a filter are provided. The method includes: determining a structure of a target filter circuit that includes a capacitor and a first optional component; reserving a first circuit region; disposing the first optional component in the first circuit region, and electrically connecting the first optional component, through a plurality of first wires located in a first metal layer, to a plurality of first external nodes that are outside the first circuit region; electrically connecting the plurality of first external nodes to a plurality of second wires located in a second metal layer, respectively, in which the second wires are disposed around the first circuit region; and disposing the capacitor in the first circuit region and above the first optional component.

### CROSS-REFERENCE TO RELATED PATENT APPLICATION

This application claims the benefit of priority to Taiwan Patent Application No. 110146660, filed on Dec. 14, 2021. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an integrated circuit layout and an integrated circuit layout method, and more particularly to an integrated circuit layout and an integrated circuit layout method for a filter.

### BACKGROUND OF THE DISCLOSURE

The filter is a commonly used circuit for filtering high frequency electronic noise or filtering out specific frequency electronic noises. Reference is made to FIGS. 1 to 4, which are first, second, third and fourth schematic diagrams of existing filter circuits, respectively.

As shown in FIGS. 1 to 4, in general, filters used in an integrated circuit are composed of resistors and capacitors, or transistors and capacitors. Areas of the transistors, resistors and capacitors selected for used are minimized as much as possible to reduce costs of wafer manufacturing. At present, circuit designs are aimed at saving space in order to achieve higher area utilization and better cost control.

Reference is further made to FIG. 5, which is a layout diagram of an existing filter circuit. As shown in FIG. 5, this filter 5 uses a field effect transistor 50 and a capacitor 52. A plurality of metal wires ML1 of the field effect transistor 50 are located in a first metal layer above the field effect transistor 50, and a plurality of metal wires ML2 are located in a second metal layer above the field effect transistor 50. The metal wires ML1 are connected to the metal wires ML2 through a dielectric layer V1 with vias, the second metal layer is located above the first metal layer, and the capacitor 52 is disposed adjacent to the field effect transistor 50. However, this layout requires reserving of an area to be used by the field effect transistor 50 and the capacitor 52, and since the capacitor 52 merely uses metal plates MP2, MP3, MP4 in an upper metal layer without utilizing spaces of a lower metal layer, an optimal area utilization rate cannot be achieved.

Therefore, improving the circuit layout to save area so as to achieve a higher area utilization rate has become an important issue to be addressed in the related art.

### SUMMARY OF THE DISCLOSURE

In response to the above-referenced technical inadequacies, the present disclosure provides an integrated circuit layout and integrated circuit layout method for a filter that can increase an area utilization rate of a capacitor and reduce an area that causes external noise coupling.

In one aspect, the present disclosure provides an integrated circuit layout method for a filter, the integrated circuit layout method includes: determining a structure of a target filter circuit, in which the target filter circuit includes a capacitor and a first optional component, and the first optional component is a first resistor or a first fin field-effect transistor (finFET); reserving a first circuit region at a predetermined position in a circuit layout; disposing the first optional component in the first circuit region, and electrically connecting the first optional component, through a plurality of first wires located in a first metal layer, to a plurality of first external nodes that are outside the first circuit region; electrically connecting the plurality of first external nodes to a plurality of second wires located in a second metal layer, respectively, in which the second wires are disposed around the first circuit region, and the second metal layer is located on the first metal layer; and disposing the capacitor in the first circuit region and above the first optional component, in which the capacitor has a first metal plate and a second metal plate that are disposed opposite to each other, and the first metal plate and the second metal plates are respectively located in two of the second metal layer and the at least one third metal layer above the second metal layer.

In another aspect, the present disclosure provides an integrated circuit layout for a filter, and the integrated circuit layout includes a target filter circuit, a plurality of first wires, and a plurality of second wires. The target filter circuit is disposed at a predetermined position in a circuit layout, the target filter circuit includes a capacitor and a first optional component, and the first optional component is a first resistor or a first transistor and is disposed in a first circuit region. The plurality of first wires are located in a first metal layer, and respectively used for electrically connecting the first optional element to a plurality of first external nodes outside the first circuit region. The plurality of second wires are located in a second metal layer and disposed around the first circuit region, wherein the plurality of second wires are respectively used to electrically connect the first external nodes, and the second metal layer is located above the first metal layer, in which the capacitor is disposed in the first circuit region and above the first optional component, the capacitor has a first metal plate and a second metal plate that are disposed opposite to each other, and the first metal plate and the second metal plates are respectively located in two of the second metal layer and the at least one third metal layer above the second metal layer.

Therefore, in the integrated circuit layout and integrated circuit layout method for a filter provided by the present disclosure, a plurality of external nodes of the first optional component and/or the second optional component can be guided to a periphery of the capacitor reserve area through the wires that are arranged in the first metal layer, so as to allow the capacitor to be disposed above the first optional element and the second optional element to utilize unused multiple metal layers. Therefore, not only the capacitance area utilization can be increased, but the area used by the filter can also be reduced by about 50%, thereby enabling costs associated with wafer area to be lowered, and an area that causes external noise coupling to be reduced.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIGS. 1 to 4 are first, second, third and fourth schematic diagrams of existing filter circuits, respectively;

FIG. 5 is a layout diagram of an existing filter circuit;

FIG. 6 is a flowchart of an integrated circuit layout method for a filter according to a first embodiment of the present disclosure;

FIGS. 7A and 7B are respectively first and second schematic top views of an integrated circuit layout for a filter according to the first embodiment of the present disclosure;

FIG. 8 is a schematic side view of FIG. 7B along a cross-sectional line A-A;

FIG. 9 is a flowchart of an integrated circuit layout method for a filter according to a second embodiment of the present disclosure;

FIGS. 10A and 10B are respectively first and second schematic top views of an integrated circuit layout for a filter according to the second embodiment of the present disclosure; and

FIG. 11 is a schematic side view of FIG. 10B along a cross-sectional line B-B.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

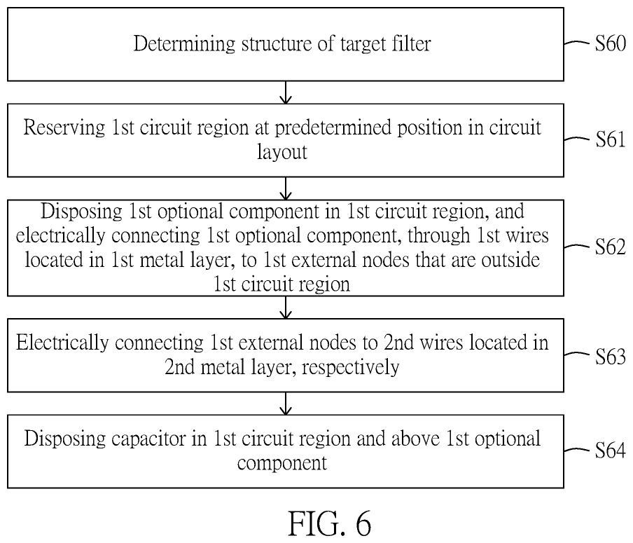

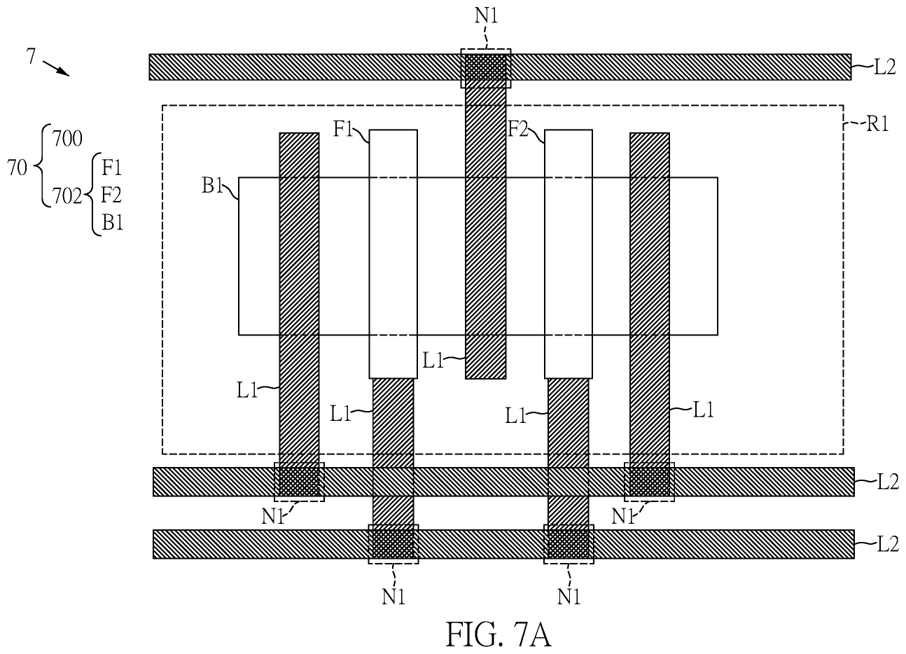

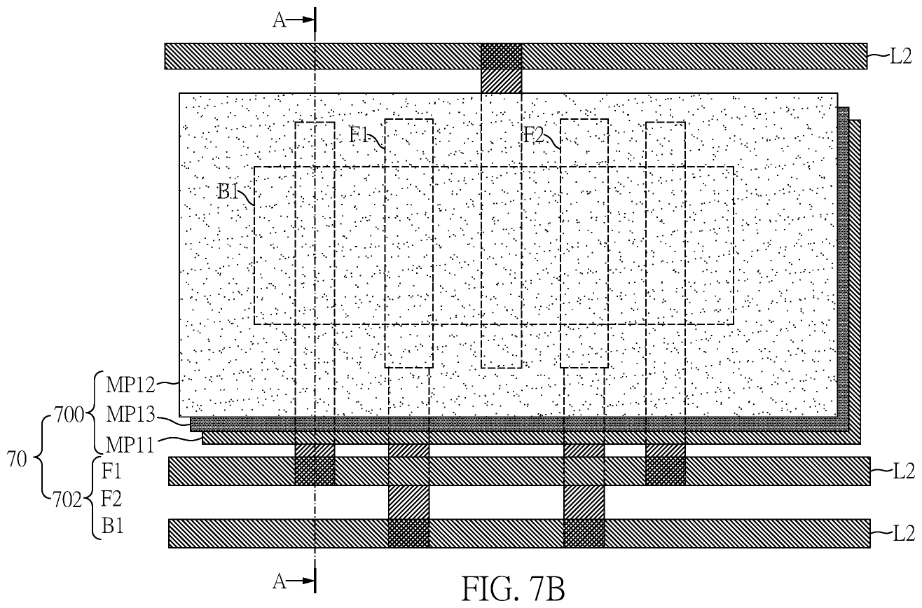

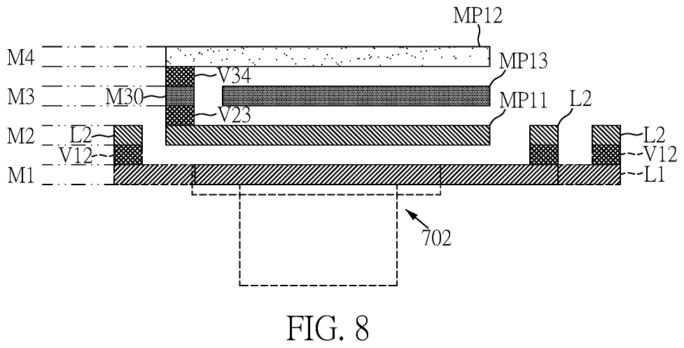

Referring to FIGS. 6 to 8, FIG. 6 is a flowchart of an integrated circuit layout method for a filter according to a first embodiment of the present disclosure, FIGS. 7A and 7B are respectively first and second schematic top views of an integrated circuit layout for a filter according to the first embodiment of the present disclosure, and FIG. 8 is a schematic side view of FIG. 7B along a cross-sectional line A-A.

As shown in FIG. 6, the first embodiment of the present disclosure provides an integrated circuit layout method for a filter, the integrated circuit layout method includes the following steps:

Step S60: determining a structure of a target filter circuit.

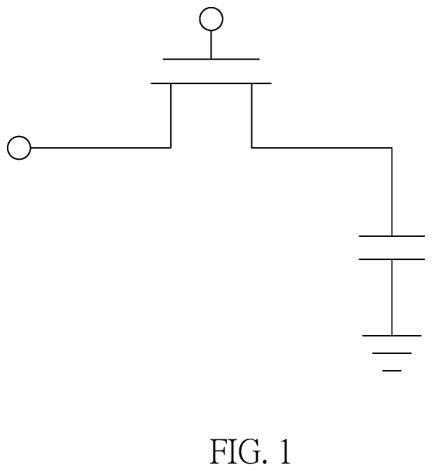

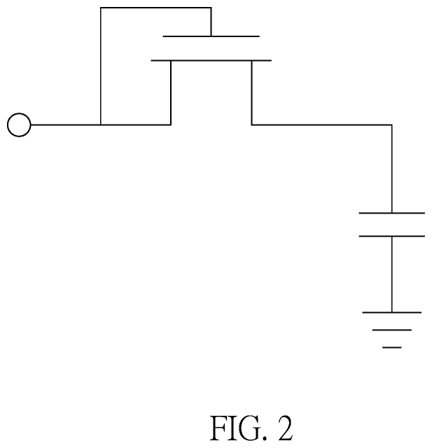

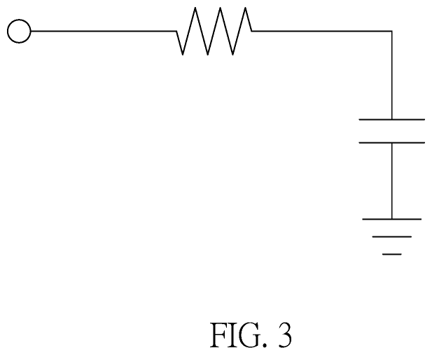

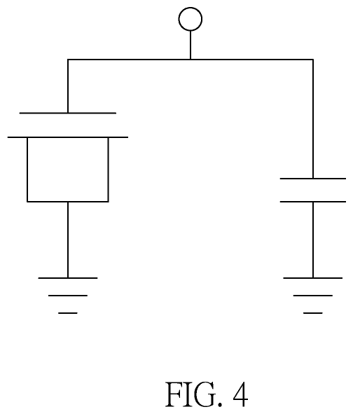

Referring to compositions of the existing filter circuits shown in FIGS. 1 to 4, in the integrated circuit layout 7 of FIG. 7A, the target filter circuit 70 can include a capacitor 700 and a first optional component, and the first optional component can be a resistor or a fin field-effect transistor (finFET). In FIGS. 7A and 7B, a first finFET 702 is taken as an example of the first optional component, and the first finFET includes fins F1, F2 and a substrate B1 as shown in FIGS. 7A and 7B.

Step S61: reserving a first circuit region at a predetermined position in a circuit layout. Specifically, a first circuit region is a capacitor reserved region, which is used for arranging a capacitor provided in subsequent steps.

As shown in FIG. 7A, in the schematic top view of a circuit layout 7, a first circuit region R1 is reserved in advance.

Step S62: disposing the first optional component in the capacitor reserved region, and electrically connecting the first optional component, through a plurality of first wires located in a first metal layer, to a plurality of first external nodes that are outside the capacitor reserved region.

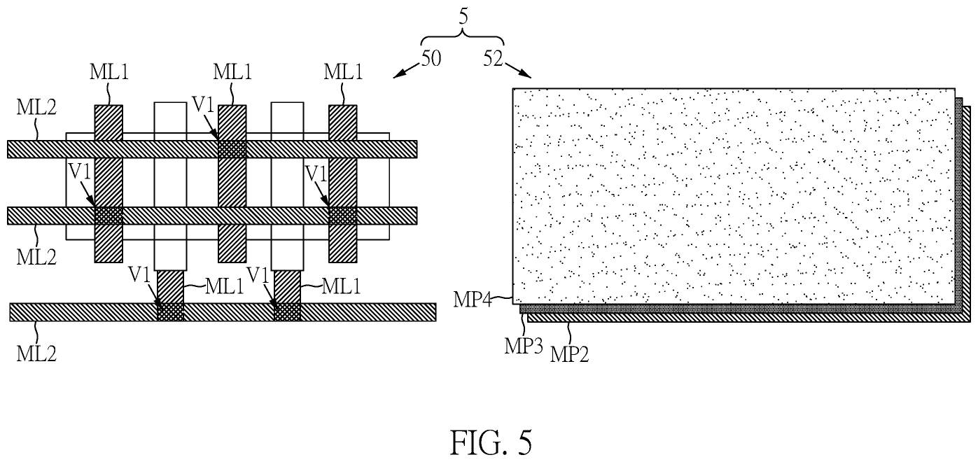

Taking FIG. 7A as an example, the first finFET 702 can be disposed in the first circuit region R1, and the first finFET 702 can be electrically connected to, through a plurality of first wires L1 located in a first metal layer M1, a plurality of first external nodes N1 outside the capacitor reserve area R1. The plurality of external nodes N1 are used to respectively electrically connect a source, a drain, and a gate of the first finFET 702, and the number of the source, drain, and gate is not limited to that in the structure of FIG. 7A. Compared with FIG. 5, in the first embodiment of the present disclosure, the plurality of first external nodes N1 are further designed at the outside of the first circuit region R1. It can be further seen from the top view that a shape of the first circuit region R1 is substantially the same as a shape and a size of an area to be occupied by the capacitor 700. Therefore, the first circuit region R1 is not limited to a rectangle shown in FIG. 7A, and can be, for example, a circle or a polygon.

Step S63: electrically connecting the plurality of first external nodes to a plurality of second wires located in a second metal layer, respectively.

As shown in FIG. 7A, a plurality of second wires L2 located in a second metal layer M2 are arranged around the capacitor reserve region R1, and are electrically connected to the plurality of first external nodes N1, respectively, and the second metal layer M2 is located above the first metal layer M1. In some embodiments, a part of the plurality of second wires L2 can be disposed at a first side of the first circuit region R1 (for example, at an upper side of the first circuit region R1 in FIG. 7A), and the other part of the plurality of second wires L2 can be disposed at a second side of the first circuit region R1, for example, at a lower side of the first circuit region R1 in FIG. 7A.

In addition, as shown in FIGS. 7A, 7B and 8, each of the plurality of second wires L2 can be electrically connected to the corresponding first wire L1 through a dielectric layer V12 having a via.

Step S64: disposing the capacitor in the capacitor reserved region and above the first optional component.

As shown in FIG. 7B, the capacitor 700 is in the first circuit region R1 and above the first finFET 702, and the capacitor 700 has a first metal plate MP11 and a second metal plate MP12 that are disposed to each other.

According to different circuit design requirements, the first metal plate MP11 and the second metal plate MP12 can be respectively located in two of the second metal layer M2 and multiple metal layers above the second metal layer M2. Taking 1P4M process shown in FIG. 8 as an example, a third metal layer M3 and a fourth metal layer M4 are disposed above the second metal layer M2, and the first metal plate MP11 and the second metal plate MP12 are respectively defined as bottom and top layers of the capacitor 700. In FIG. 8, the first metal plate MP11 is disposed in the second metal layer M2, and the second metal plate MP12 is disposed in the fourth metal layer M4 and is electrically connected to the first metal plate MP11. However, the present disclosure does not limit a manner by which the first metal plate MP11 and the second metal plate MP12 are selected from the metal layers. For example, the first metal plate MP11 and the second metal plate MP12 can be selected from the second metal layer M2 to a seventh metal layer (not shown) according to the design requirements. In other words, the capacitor 700 can be provided in the second metal layer M2 and the additional metal layers provided on the second metal layer M2, and the number of the additional metal layers can be 1, 2, 3, 4, or 5. All the metal plates or metals arranged in the second metal layer M2 to the seventh metal layer can be made of conductive metal plates, for example, aluminum plates, steel plates, copper plates, invar plates, aluminum plates, or the like.

The first metal plate MP11 can be electrically connected to the second metal plate MP12 through dielectrics V23 and V34 with vias and the metal M30, a third metal plate MP13 located in the third metal layer M3 is further provided between the first metal plate MP11 and the second metal plate MP12, and a plurality of gaps interspersed between the first metal plate MP11, the second metal plate MP12, and the third metal plate MP13 are filled with dielectric. In this structure, a capacitor formed between the first metal plate MP11 and the third metal plate MP13 can be connected in parallel with a capacitor formed between the second metal plate MP11 and the third metal plate MP13. However, the structure of the capacitor 700 provided in this embodiment is only an example, and the present disclosure is not limited thereto.

Furthermore, it should be noted that the first finFET 702 taken as the first optional component is not higher than the first metal layer M1 in position, so as to avoid occupying usable space for the capacitor 700.

Therefore, as shown in FIG. 7B, in the circuit layout 7 for the filter generated by the integrated circuit layout method provided by the present disclosure, the capacitor 700 is disposed on the first finFET 702, and the plurality of external nodes N1 are guided to a periphery of the first circuit region R1 through the plurality of first wires L1 for the first finFET 702, such that the second metal layer M2 to the fourth metal layer M4 can be utilized by the capacitor 700. Therefore, compared to the circuit layout of FIG. 5, since the number of metal layers of the capacitor will not be reduced by too much due to the wiring of the field-effect transistor, a capacitance per unit area of the capacitor of the filter will not be reduced, and the area that is used can be reduced by about 50%. Therefore, wafer area costs and an area that causes external noise coupling can be reduced.

### Second Embodiment

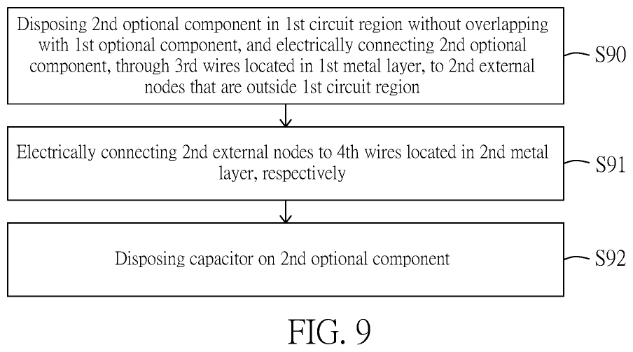

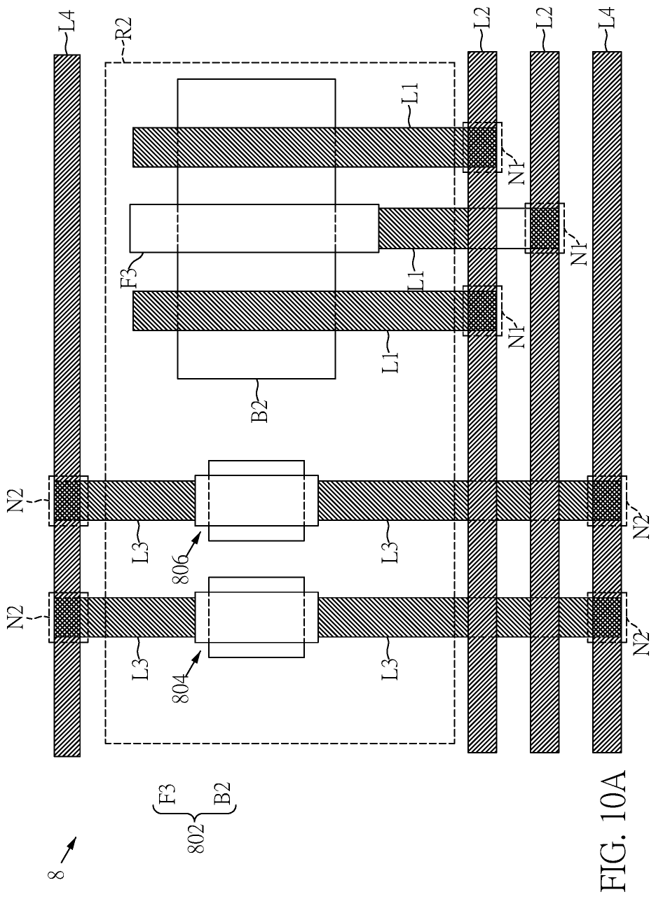

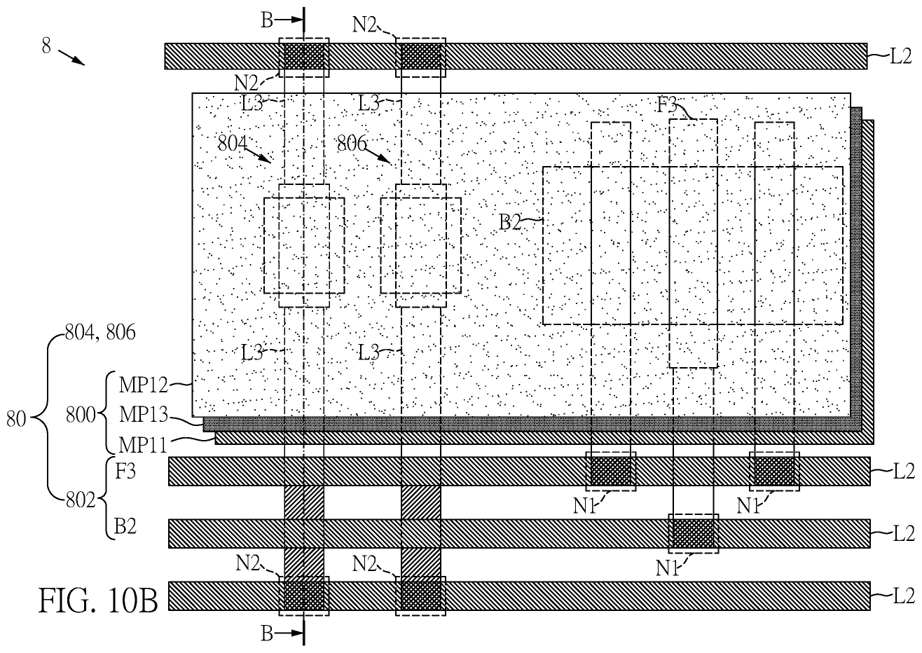

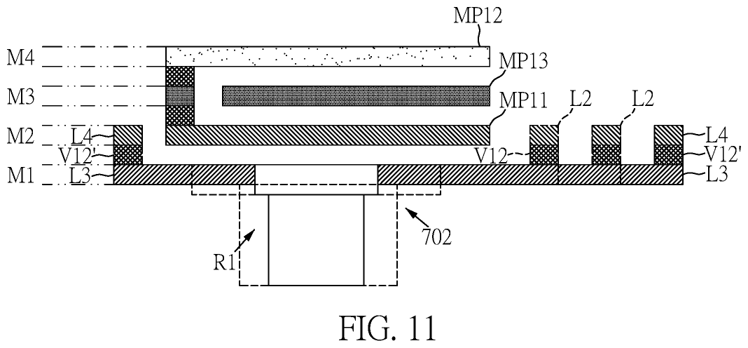

Referring to FIGS. 9 to 11, FIG. 9 is a flowchart of an integrated circuit layout method for a filter according to a second embodiment of the present disclosure, FIGS. 10A and 10B are respectively first and second schematic top views of an integrated circuit layout for a filter according to the second embodiment of the present disclosure, and FIG. 11 is a schematic side view of FIG. 10B along a cross-sectional line B-B.

Referring to FIGS. 1 to 4 and 6 first, the target filter circuit 80 of this embodiment can further include a second optional component, and the second optional component can also be a resistor or a finFET. In the first embodiment, since the first finFET 702 is used as the first optional component, resistors 804 and 806 are used as the second optional component in this embodiment. Therefore, as shown in FIG. 10B, the target filter circuit 80 determined in step S60 can include a capacitor 800, a first finFET 802, and the resistors 804 and 806.

As shown in FIG. 9, the integrated circuit layout method of the second embodiment of the present disclosure can further include the following steps:

Step S90: disposing the second optional component in the capacitor reserved region without overlapping with the first optional component, and electrically connecting the second optional component, through a plurality of third wires located in the first metal layer, to a plurality of second external nodes that are outside the capacitor reserved region.

Taking FIG. 10A as an example, it is similar to FIG. 7A in that the first finFET 802 includes a fin F3 and a substrate B2 in the integrated circuit layout 8, in which the first finFET 802 is disposed in a capacitor reserved region R2, and the first finFET 802 is electrically connected to, through a plurality of first wires L1 located in a first metal layer M1, a plurality of first external nodes N1 outside the capacitor reserve area R2.

On the other hand, the second optional component can include, for example, the resistors 804 and 806, which are arranged in the capacitor reserved region R2 without overlapping with the first finFET 802, and the resistors 804 and 806 are connected to, through a plurality of third wires L3 located in the first metal layer M1, to a plurality of second external nodes N2 that are outside the capacitor reserved region R2. Layouts of the resistors 804 and 806 are known to those skilled in the arts, and the repeated descriptions are omitted hereinafter. Only the structure of the resistors and connection relationships between the resistors with the plurality of second external nodes N2 are exemplarily shown in FIG. 10A.

Compared with FIG. 5, in the second embodiment of the present disclosure, the plurality of second external nodes N2 are further designed to be at the outside of the capacitor reserved region R2. It can be further seen from the top view that a shape of the capacitor reserved region R2 is substantially the same as a shape and a size of an area to be occupied by the capacitor 800. Therefore, the capacitor reserved region R2 is not limited to being a rectangle as shown in FIG. 10A, and can be, for example, a circle or a polygon.

Step S91: electrically connecting the plurality of second external nodes to a plurality of fourth wires located in a second metal layer, respectively.

The similarities between this embodiment and FIG. 7A are omitted here. In FIG. 10A, a plurality of fourth lines L4 located in the second metal layer M2 are disposed around the capacitor reserved region R2, and are electrically connected to the plurality second External node N2, respectively. It should be noted that the plurality of fourth wires L4 are disposed around the capacitor reserved region R2 without overlapping with the plurality of second wires L2.

In some embodiments, a part of the plurality of fourth wires L4 can be disposed at a first side of the capacitor reserved region R2 (for example, at an upper side of the capacitor reserved region R2 in FIG. 10A), and the other part of the plurality of fourth wires L4 can be disposed at a second side of the capacitor reserved region R2, for example, at a lower side of the capacitor reserved region R2 in FIG. 10A.

In addition, as shown in FIGS. 10A, 10B and 11, each of the plurality of fourth wires L4 can be electrically connected to the corresponding third wire L3 through a dielectric layer V12′ having a via.

Step S92: disposing the capacitor on the second optional component.

As shown in FIG. 10B, the capacitor 800 is disposed in the capacitor reserved region R2, and is disposed above the first finFET 802 and the resistors 804 and 806. Similar to the first embodiment, the second optional component, such as resistors 804 and 806, should not be higher than the first metal layer M1 in position.

Therefore, as shown in FIG. 10B, in the circuit layout 8 for the filter generated by the integrated circuit layout method provided by the present disclosure, the capacitor 800 is disposed on the first finFET 702 and the resistors 804 and 806, and the plurality of external nodes N1 are guided to a periphery of the capacitor reserved region R2 through the plurality of first wires L1 for the first finFET 802, the plurality of external nodes N2 are guided to a periphery of the capacitor reserved region R2 through the plurality of third wires L1 for the resistor 804 and 806, such that the capacitor 800 can use the second metal layer M2 to the fourth metal layer M4. Therefore, compared to the circuit layout of FIG. 5, since the number of metal layers of the capacitor will not be reduced by too much due to the wiring of the field-effect transistor, a capacitance per unit area of the capacitor of the filter will not be reduced, and the area that is used can be reduced by about 50%. Therefore, wafer area costs and an area that causes external noise coupling can be reduced.

### Beneficial Effects of the Embodiments

In conclusion, in the integrated circuit layout and integrated circuit layout method for a filter provided by the present disclosure, a plurality of external nodes of the first optional component and/or the second optional component can be guided to a periphery of the capacitor reserve area through the wires that are arranged in the first metal layer, so as to allow the capacitor to be disposed above the first optional element and the second optional element to utilize unused multiple metal layers. Therefore, not only the capacitance area utilization can be increased, but the area used by the filter can also be reduced by about 50%, thereby enabling costs associated with wafer area to be lowered, and an area that causes external noise coupling to be reduced.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An integrated circuit layout method for a filter, the integrated circuit layout method comprising:
determining a structure of a target filter circuit, wherein the target filter circuit includes a capacitor and a first optional component, and the first optional component is a first resistor or a first fin field-effect transistor (finFET);
reserving a first circuit region at a predetermined position in a circuit layout;
disposing the first optional component in the first circuit region, and electrically connecting the first optional component, through a plurality of first wires located in a first metal layer, to a plurality of first external nodes that are outside the first circuit region;
electrically connecting the plurality of first external nodes to a plurality of second wires located in a second metal layer, respectively, wherein the second wires are disposed around the first circuit region, and the second metal layer is located on the first metal layer; and
disposing the capacitor in the first circuit region and above the first optional component, wherein the capacitor has a first metal plate and a second metal plate that are disposed opposite to each other, and the first metal plate and the second metal plates are respectively located in two of the second metal layer and the at least one third metal layer above the second metal layer.

2. The integrated circuit layout method according to claim 1, wherein the first optional component is not higher than the first metal layer in position.

3. The integrated circuit layout method according to claim 1, wherein the target filter circuit further includes a second optional element, and in response to the first optional element being the first resistor, the second optional element is a second finFET, in response to the first optional element being the first finFET, the second optional element is a second resistor.

4. The integrated circuit layout method according to claim 3, further comprising:
disposing the second optional component in the first circuit region without overlapping with the first optional component, and electrically connecting the second optional component, through a plurality of third wires located in the first metal layer, to a plurality of second external nodes that are outside the first circuit region;
electrically connecting the plurality of second external nodes to a plurality of fourth wires in the second metal layer, respectively, wherein the plurality of fourth wires are disposed around the first circuit region without overlapping with the plurality of second wires; and
disposing the capacitor on the second optional component.

5. The integrated circuit layout method according to claim 4, wherein the second optional component is not higher than the first metal layer in position.

6. The integrated circuit layout method according to claim 1, further comprising:
disposing a part of the plurality of second wires at a first side of the first circuit region, and disposing another part of the plurality of second wires at a second side of the first circuit region.

7. The integrated circuit layout method according to claim 1, wherein a quantity of the at least one third metal layer is one, two, three, four, or five.

8. The integrated circuit layout method according to claim 1, wherein a first circuit region is a capacitor reserved region.

9. An integrated circuit comprising:
a target filter circuit disposed at a predetermined position in a circuit layout, wherein the target filter circuit includes a capacitor and a first optional component, the first optional component being one of a first resistive circuit and a first transistor and being disposed in a first circuit region;
a plurality of first wires in a first metal layer, for respectively and electrically coupling the first optional element to a plurality of first external nodes outside the first circuit region; and
a plurality of second wires in a second metal layer and disposed around the first circuit region, wherein the plurality of second wires are for respectively and electrically coupling the first external nodes, and the second metal layer is above the first metal layer,
wherein the capacitor is disposed in the first circuit region and above the first optional component, the capacitor has a first metal plate and a second metal plate that are disposed opposite to each other, and the first metal plate and the second metal plates are respectively located in two of the second metal layer and the at least one third metal layer above the second metal layer.

10. The integrated circuit according to claim 9, wherein the first optional component is not higher than the first metal layer in position.

11. The integrated circuit according to claim 9, wherein the target filter circuit further includes a second optional element, and in response to the first optional element being the first resistor, the second optional element is a second finFET, in response to the first optional element being the first finFET, the second optional element is a second resistor.

12. The integrated circuit of claim 11, wherein the second optional component is disposed in the first circuit region without overlapping with the first optional component, and the integrated circuit further comprises:
a plurality of third wires located in the first metal layer, and respectively used for electrically connecting the second optional element to a plurality of second external nodes outside the first circuit region; and
a plurality of fourth wires located in the second metal layer and respectively electrically connected to the plurality of second external nodes, wherein the fourth wires are disposed around the first circuit region without overlapping with the plurality of second wires,
wherein the capacitor is disposed above the second optional component.

13. The integrated circuit according to claim 12, wherein the second optional component is not higher than the first metal layer in position.

14. The integrated circuit according to claim 9, wherein a part of the plurality of second circuits is disposed at a first side of the first circuit region, and another part of the plurality of second wires is arranged at a second side of the first circuit region.

15. The integrated circuit according to claim 9, wherein a quantity of the at least one third metal layer is one, two, three, four, or five.

16. The integrated circuit according to claim 9, wherein a first circuit region is a capacitor reserved region.
